(19) United States
(12) Patent Application Publication
(10) Pub. No.: US 2019/0214998 A1
(43) Pub. Date: Jul. 11, 2019

(54) DELAY LOCKED LOOP CIRCUIT

(71) Applicant: FUJITSU LIMITED, Kawasaki-shi (JP)

(72) Inventors: Ikuo Soga, Isehara (JP); Kazuaki Oishi, Yokohama (JP); Hiroshi Matsumura, Atsugi (JP); Yoichi Kawano, Setagaya (JP); Yasuhiro Nakasha, Hadano (JP)

(73) Assignee: FUJITSU LIMITED, Kawasaki-shi (JP)

(21) Appl. No.: 16/355,488

(22) Filed: Mar. 15, 2019

Related U.S. Application Data
(63) Continuation of application No. PCT/JP2018/004823, filed on Feb. 13, 2018.

(30) Foreign Application Priority Data
Mar. 28, 2017 (JP) 2017-063390

(51) Int. Cl. H03L 7/081; H03K 5/134; H03L 7/089; H04L 7/00

(52) U.S. Cl. CPC H03L 7/0812; H03K 5/134; H04L 7/0037; H04L 7/0091; H03L 7/0891

(57) ABSTRACT

A delay locked loop circuit includes a first delay circuit that includes a plurality of first delay devices and a plurality of second delay devices, the plurality of first delay devices and the plurality of second delay devices are coupled in series with each other, a second delay circuit that includes a plurality of third delay devices equal in number and identical in configuration to the plurality of second delay devices, the plurality of third delay devices are coupled in series with each other, a phase comparator that outputs a phase difference between a first delayed clock output from the first delay circuit and a second delayed clock output from the second delay circuit, a first control circuit that outputs a first control signal that controls a time, and a second control circuit that outputs a second control signal.

### CROSS-REFERENCE TO RELATED APPLICATION

This application is a continuation application of International Application PCT/JP2018/004823 filed on Feb. 13, 2018 and designated the U.S., the entire contents of which are incorporated herein by reference. The International Application PCT/JP2018/004823 is based upon and claims the benefit of priority of the prior Japanese Patent Application No. 2017-063390, filed on Mar. 28, 2017, the entire contents of which are incorporated herein by reference.

### FIELD

The embodiments discussed herein are related to a delay locked loop (DLL) circuit.

### BACKGROUND

There is a delay locked loop circuit which outputs a control voltage that realizes a certain delay time according to the number of delay buffers included in a delay circuit through which an input clock passes and the frequency of the input clock.

The delay locked loop circuit includes a delay circuit including delay buffers in a plurality of stages, a phase comparator, a charge pump, and a capacitance. The phase comparator compares the input clock passed through the delay circuit and the input clock not passed through the delay circuit with each other. When the phases of the two input clocks differ from each other, the voltage of the capacitance is changed by a current from the charge pump, and the voltage of the capacitance is fed back as a control voltage of each delay buffer. When a locked state is reached in which the phases of the two input clocks coincide with each other, the voltage (control voltage) of the capacitance becomes fixed. In this locked state, the cycle of the input clock and a total delay time obtained by summing the respective delay times of N delay buffers coincide with each other. It is therefore possible to obtain a control voltage for generating N clocks different in phase in steps of (360/N)° with respect to the input clock by the N delay blocks.

In the delay locked loop circuit, it is preferable to expand a time range (dynamic range) in which the delay devices may delay the clock in order to achieve a secure locked state even when there are changes in an operating environment (power supply variations, temperature changes, and the like) and variations between lots (see a left diagram in FIG. 1). On the other hand, it is preferable to reduce a rate of change (gain) of the delay time of each delay device with respect to the control voltage in order to reduce a change of the control voltage in response to noise mixed in the delay device (see a right diagram in FIG. 1).

However, the expansion of the dynamic range and the reduction of the gain are in a trade-off relation to each other. Therefore, it is difficult to achieve both the expansion of the dynamic range and the reduction of the gain, and it is difficult to control the delay time with high accuracy.

The followings are reference documents.
[Document 1] Japanese Laid-open Patent Publication No. 2016-082278 and
[Document 2] Japanese Laid-open Patent Publication No. 10-079663.

### SUMMARY

According to an aspect of the embodiments, a delay locked loop circuit includes a first delay circuit that includes a plurality of first delay devices and a plurality of second delay devices, the plurality of first delay devices and the plurality of second delay devices are coupled in series with each other, a second delay circuit that includes a plurality of third delay devices equal in number and identical in configuration to the plurality of second delay devices, the plurality of third delay devices are coupled in series with each other, a phase comparator that outputs a phase difference between a first delayed clock output from the first delay circuit and a second delayed clock output from the second delay circuit, a first control circuit that outputs a first control signal that controls a time by which the clock is delayed in each first delay device according to the phase difference, and a second control circuit that outputs a second control signal that controls a time by which the clock is delayed in each second delay device and each third delay device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of relation between control voltage and delay time;

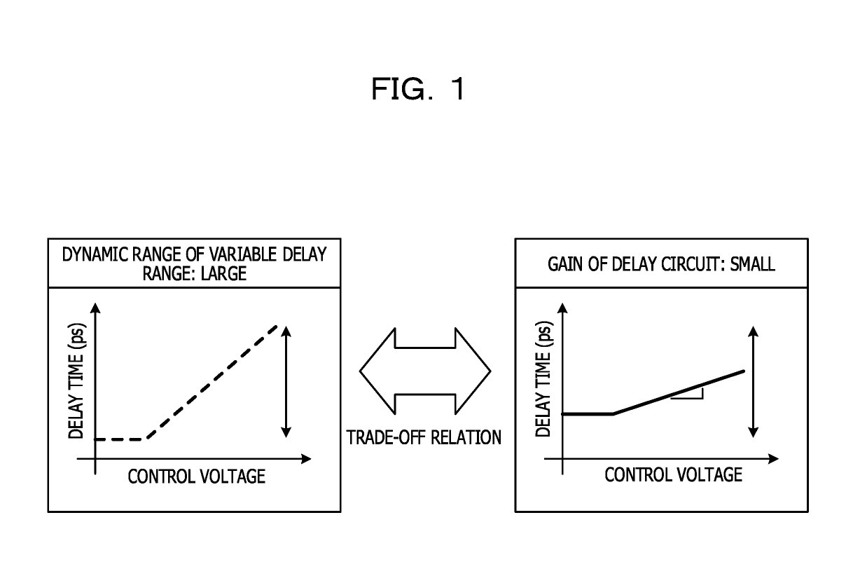

FIG. 2 is a diagram illustrating an example of a configuration of an impulse radio communication system;

FIG. 3 is a diagram illustrating an example of a configuration of a DLL circuit;

FIG. 4 is a diagram illustrating an example of delay time characteristics of a delay device;

FIG. 5 is a diagram illustrating an example of a configuration of delay devices;

FIG. 6 is a diagram illustrating an example of delay time characteristics in the configuration illustrated in FIG. 5;

FIG. 7 is a diagram illustrating an example of a configuration of a DLL circuit;

FIG. 8 is a diagram illustrating an example of a configuration of a pulse position modulator;

FIG. 9 is a diagram illustrating an example of variations in delay time generated by a delay circuit;

FIG. 10 is a diagram illustrating an example of delay device characteristics;

FIG. 11 is a diagram illustrating an example of a configuration of a delay device;

FIG. 12 is a diagram illustrating an example of a configuration of a DLL circuit;

FIG. 13 is a diagram illustrating an example of a configuration of a DLL circuit;

FIG. 14 is a diagram of assistance in explaining an example of a control voltage generating method; and

FIG. 15 is a flowchart illustrating an example of a control voltage generating method.

### DESCRIPTION OF EMBODIMENTS

Description will hereinafter be made of embodiments of a delay locked loop circuit according to the present disclosure.

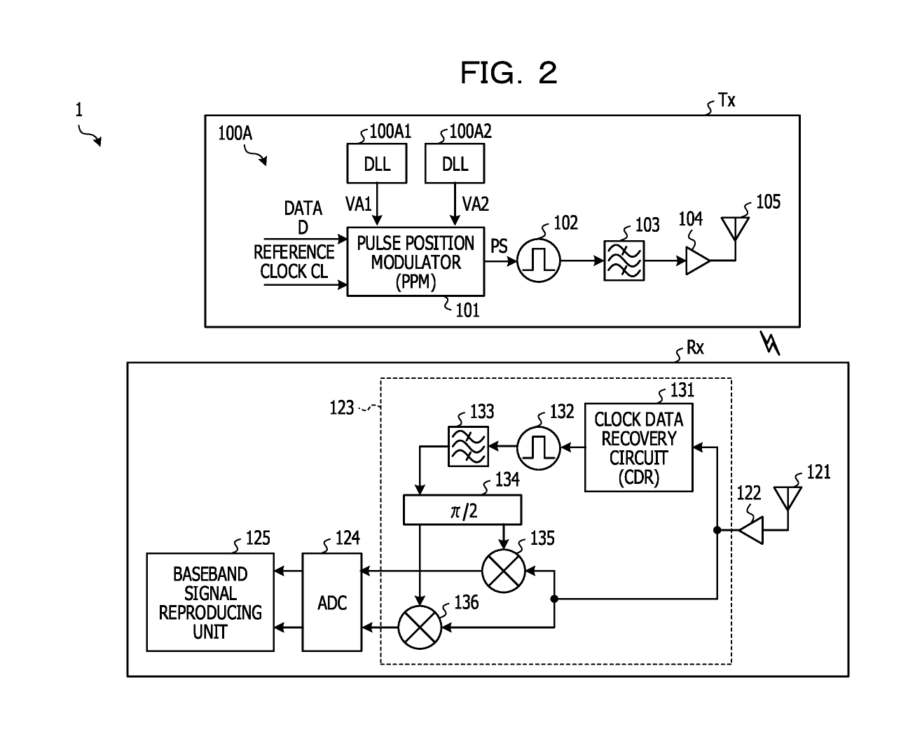

FIG. 2 is a diagram illustrating an example of a configuration of an impulse radio communication system in which a delay locked loop circuit is used. An impulse radio communication system 1 illustrated in FIG. 2 performs radio communication by an impulse method using radio frequency (RF) pulses as a transmission medium. The impulse radio communication system 1 includes an impulse transmitter Tx and an impulse receiver Rx.

The impulse transmitter Tx includes a DLL circuit 100A, a pulse position modulation (PPM) circuit 101, a pulse generator 102, a band-pass filter 103, a transmitting amplifier 104, and a transmitting antenna 105.

The DLL circuit 100A supplies the PPM circuit 101 with a control signal that controls a delay time by which a reference clock CL is delayed. The reference clock CL is an example of a clock. The DLL circuit 100A in a mode illustrated in FIG. 2 includes DLL units 100A1 and 100A2 that generate two kinds of control voltages VA1 and VA2. The control voltage VA1 generated by the DLL unit 100A1 and the control voltage VA2 generated by the DLL unit 100A2 are each an example of a control signal that controls a delay time by which the reference clock CL is delayed.

The PPM circuit 101 generates a pulsed modulated signal PS by delaying the reference clock CL by a delay time corresponding to input data D. The PPM circuit 101 outputs the modulated signal PS to the pulse generator 102. The input data D is an example of data input to the pulse position modulation circuit 101.

The pulse generator 102 generates a pulse of a given pulse width when detecting an edge (for example, a rising edge) of the modulated signal PS in a time slot. The band-pass filter 103 outputs a filter passed pulse (for example, a millimeter-wave pulse) by subjecting the pulse generated by the pulse generator 102 to filtering that passes only a given pass frequency band. The given pass frequency band, for example, has a pass lower limit frequency of 80 GHz, a pass upper limit frequency of 90 GHz, and a pass frequency bandwidth of 10 (=90−80) GHz.

The output of the band-pass filter 103 is input to the transmitting amplifier 104. For example, the millimeter-wave pulse is amplified by the transmitting amplifier 104, and thereby a transmission signal (impulse signal) is radio-transmitted via the transmitting antenna 105. The transmission signal transmits data “1” or “0” corresponding to the presence or absence of the millimeter-wave pulse.

The impulse receiver Rx includes a receiving antenna 121, a receiving amplifier 122, a detector 123, an analog-to-digital converter (ADC) 124, and a baseband signal reproducing unit 125.

The receiving amplifier 122 amplifies a received signal (impulse signal) radio-received via the receiving antenna 121, and outputs the received signal to the detector 123. The detector 123 detects an envelope of the received signal (millimeter-wave pulse) amplified by the receiving amplifier 122, and outputs the envelope of the received signal to the ADC 124.

The detector 123 includes a clock data recovery (CDR) circuit 131, a pulse generator 132, a band-pass filter 133, a first mixer 135, a second mixer 136, and a π/2 phase shifter 134.

The pulse generator 132 generates a local oscillating signal of a frequency (for example, 83.5 GHz) within the pass frequency band of the band-pass filter 103 of the impulse transmitter Tx based on the clock reconstructed by the CDR circuit 131.

The band-pass filter 133 has a pass frequency band characteristic similar to that of the band-pass filter 103 of the impulse transmitter Tx. The band-pass filter 133 generates a pulse signal corresponding to the local oscillating signal from the pulse generator 132.

The first mixer 135 performs detection by mixing the output signal of the receiving amplifier 122 with the pulse signal output by the band-pass filter 133. The second mixer 136 performs detection by mixing the output signal of the receiving amplifier 122 with a phase-shifted signal generated by the π/2 phase shifter 134 by phase-shifting the phase of the pulse signal output by the band-pass filter 133 by π/2. Intermediate frequency (IF) signals are thereby obtained.

The local oscillating signals mixed by the first mixer 135 and the second mixer 136 are shifted in phase from each other by π/2 (for example, 3 ps). A Q-signal as one of the IF signals is output from the first mixer 135. An I-signal as one of the IF signals is output from the second mixer 136.

The ADC 124 converts the analog Q-signal and the analog I-signal into digital data. The baseband signal reproducing unit 125 detects the phase of the impulse signal received by the receiving antenna 121 from the digital Q-signal and the digital I-signal. The baseband signal reproducing unit 125 reproduces data from the detected phase and the phase of the received clock.

It is to be noted that the impulse radio communication system is not limited to usage in a millimeter-wave band. For example, the impulse radio communication system is applicable to communication of an ultra wide band (UWB) (ultra-wide band radio) system including a micro-wave band and a quasi-millimeter wave band.

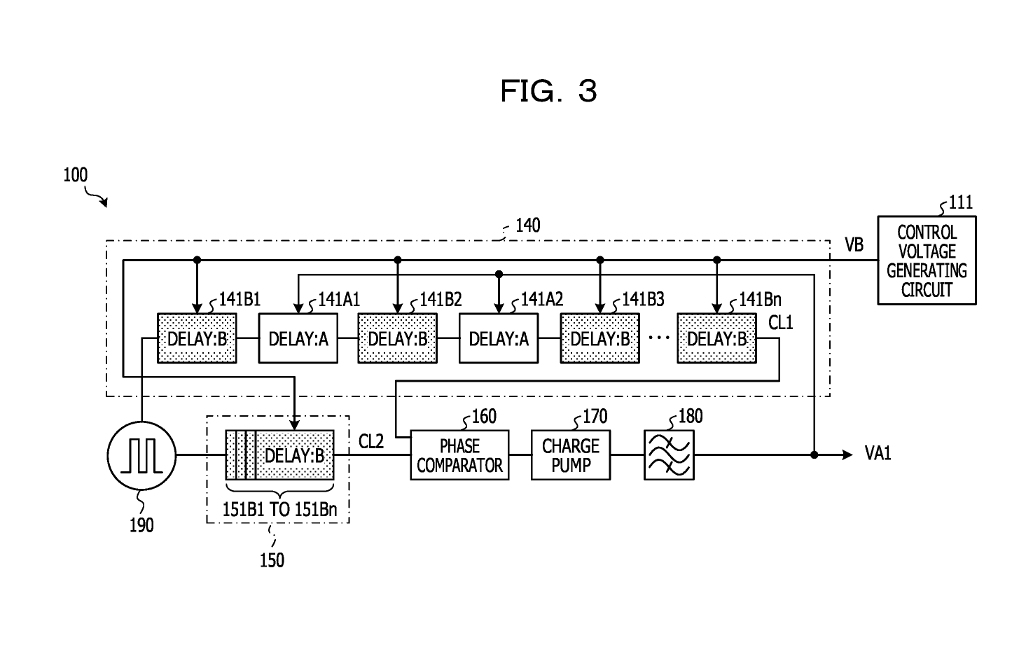

FIG. 3 is a diagram illustrating an example of a configuration of a DLL circuit according to a first embodiment of the present disclosure. A DLL circuit 100 illustrated in FIG. 3 may be applied to the DLL unit 100A1 in FIG. 2, for example. The DLL circuit 100 includes a delay circuit 140, a delay circuit 150, a phase comparator 160, a charge pump 170, a low-pass filter 180, and a control voltage generating circuit 111.

The delay circuit 140 is an example of a first delay circuit. The delay circuit 140 includes at least one delay device A and at least one delay device B. The delay circuit 140 has a configuration in which the at least one delay device A and the at least one delay device B are coupled in series with each other. The delay device A is an example of a first delay device. The delay device B is an example of a second delay device.

The delay circuit 140 includes m delay devices A (delay devices 141A1 to 141Am) having a mutually identical configuration and n delay devices B (delay devices 141B1 to 141Bn) having a mutually identical configuration. m and n each represent a natural number.

The delay circuit 150 is an example of a second delay circuit. The delay circuit 150 includes n delay devices B (delay devices 151B1 to 151Bn) having a mutually identical configuration. For example, the delay circuit 150 includes the delay devices B equal in number and identical in configuration to the n delay devices B within the delay circuit 140. The delay devices B within the delay circuit 150 are an example of a third delay device. The delay circuit 150 has a configuration in which the n delay devices B (delay devices 151B1 to 151Bn) are coupled in series with each other.

Incidentally, in a case of n=1 (for example, in a case where there is one delay device B within the delay circuit 140 and there is one delay device B within the delay circuit 150), the delay devices B being coupled in series with each other means that one delay device B is disposed.

The phase comparator 160 is an example of a circuit that compares the phase of a delayed clock CL1 obtained when an input clock 190 is passed through the delay circuit 140 and output from the delay circuit 140 with the phase of a delayed clock CL2 obtained when the input clock 190 is passed through the delay circuit 150 and output from the delay circuit 150.

The delayed clock CL1 is an example of a first delayed clock. The delayed clock CL1 represents a clock whose phase is delayed with respect to the input clock 190, the delayed clock being obtained as a result of the input clock 190 passing through all of the delay devices A and all of the delay devices B within the delay circuit 140.

The delayed clock CL2 is an example of a second delayed clock. The delayed clock CL2 represents a clock whose phase is delayed with respect to the input clock 190, the delayed clock being obtained as a result of the input clock 190 passing through all of the delay devices B within the delay circuit 150.

The phase comparator 160 compares the phase of the delayed clock CL1 and the phase of the delayed clock CL2 with each other, and outputs a signal (phase difference signal) corresponding to a phase difference between the delayed clock CL1 and the delayed clock CL2. The phase comparator 160 is not limited to a phase comparator performing only phase comparison. The phase comparator 160 may, for example, be a phase/frequency comparator that performs phase comparison in a case where the phase difference is within one cycle, and performs frequency comparison in a case where the phase difference exceeds one cycle.

The charge pump 170 outputs a control current that charges or discharges a capacitor within the low-pass filter 180 according to the phase difference signal from the phase comparator 160. The low-pass filter 180 is, for example, a first-order low-pass filter including a resistance element and the capacitor.

The voltage of the capacitor within the low-pass filter 180 is fed back as the control voltage VA1 to all of the delay devices A within the delay circuit 140. The control voltage VA1 is an example of a first control signal that controls a time by which the input clock 190 is delayed in each of the delay devices A within the delay circuit 140. The charge pump 170 and the low-pass filter 180 are an example of a first control circuit.

The control voltage generating circuit 111 is an example of a second control circuit. The control voltage generating circuit 111 outputs a control voltage VB that controls a time by which the input clock 190 is delayed in each of the delay devices B within the delay circuit 140 and each of the delay devices B within the delay circuit 150. The control voltage VB is an example of a second control signal.

When the delayed clock CL1 is advanced in phase with respect to the delayed clock CL2, for example, the phase comparator 160 generates a down signal dn that lowers the control voltage VA1. The charge pump 170 generates the control current that discharges the capacitor within the low-pass filter 180 according to the down signal dn, and thereby lowers the voltage (control voltage VA1) of the capacitor. In response to the lowering of the control voltage VA1, the operating speed of each delay device A within the delay circuit 140 is lowered, and therefore the delay time of each delay device A is lengthened. As a result, the delay time of the delay circuit 140 is lengthened, so that the phase of the delayed clock CL1 is delayed.

Conversely, when the delayed clock CL1 is delayed in phase with respect to the delayed clock CL2, the phase comparator 160 generates an up signal up that raises the control voltage VA1. The charge pump 170 generates the control current that charges the capacitor within the low-pass filter 180 according to the up signal up, and thereby raises the voltage (control voltage VA1) of the capacitor. In response to the raising of the control voltage VA1, the operating speed of each delay device A within the delay circuit 140 is raised, and therefore the delay time of each delay device A is shortened. As a result, the delay time of the delay circuit 140 is shortened, so that the phase of the delayed clock CL1 is advanced.

The DLL circuit 100 thus makes the phase of the delayed clock CL1 coincide with the phase of the delayed clock CL2 so as to attain a locked state in which the delayed clock CL1 is delayed by one cycle (360°) with respect to the delayed clock CL2. For example, in a locked state, the phase difference between the delayed clock CL1 and the delayed clock CL2 is 360°.

Here, in the mode illustrated in FIG. 3, the delay devices B in the delay circuit 140 and the delay devices B in the delay circuit 150 are equal in number and identical in configuration to each other, and have a delay time controlled by the same control voltage VB. Hence, the control voltage VA1 in a locked state may be used as a voltage that may accurately generate a total delay time (delay time TA) obtained by summing the respective delay times of the m delay devices A. For example, the DLL circuit 100 may output the control voltage VA1 in a locked state as a voltage that may accurately generate the delay time TA.

In addition, in the mode illustrated in FIG. 3, the delay time of the delay devices A is controlled by the control voltage VA1, and the delay time of the delay devices B is controlled by the control voltage VB different from the control voltage VA1. In addition, at least one delay device A is coupled in series with at least one delay device B. For example, the delay circuit 140 has one or both of a series configuration in which the output of at least one delay device B is input to at least one delay device A and a series configuration in which the output of at least one delay device A is input to at least one delay device B. FIG. 3 illustrates an example of a configuration in which a delay device A is sandwiched between delay devices B on both sides of the delay device A.

According to such a series configuration, the input of the delay device A may be changed by changing the output of the delay device B by the control voltage VB, or the output of the delay device A may be changed by changing the input of the delay device B by the control voltage VB. Hence, the DLL circuit 100 may control the delay time of the delay device A by the control voltage VA1, and besides, control the delay time of the delay device A by the control voltage VB.

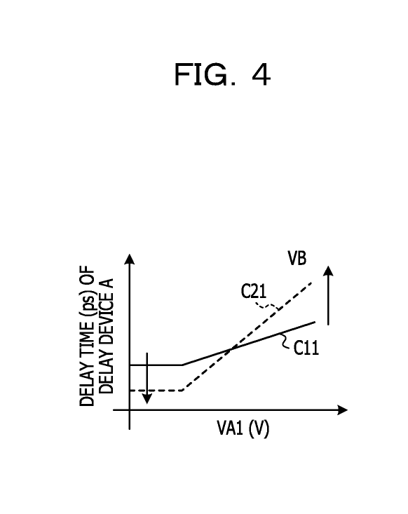

For example, as illustrated in FIG. 4, when the DLL circuit 100 is out of a locked state with the use of only the control voltage VA1, the DLL circuit 100 adjusts the delay time of the delay device A using also the control voltage VB. This changes the delay time characteristic of the delay device A from C11 to C21, so that the dynamic range of the delay device A may be expanded to a state in which a lock may be achieved. On the other hand, when the DLL circuit 100 may be maintained in a locked state by using only the control voltage VA1 without using the control voltage VB, the DLL circuit 100 adjusts the delay time of the delay device A using the control voltage VA1 without using the control voltage VB. Consequently, the delay characteristic of the delay device A becomes C11. Thus, the dynamic range of the delay device A is narrowed (gain of the delay device A is reduced), and resistance to noise in a locked state may be increased. Thus, according to the present embodiment, it is possible to achieve both the expansion of the dynamic range and the reduction of the gain, and therefore control the delay time with high accuracy.

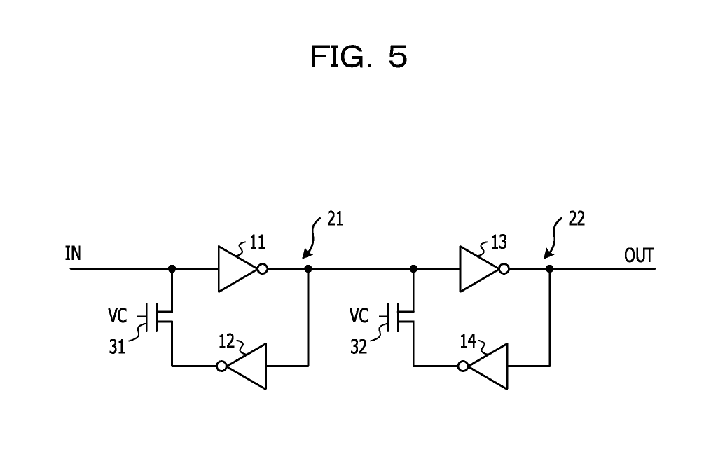

FIG. 5 is a diagram illustrating one concrete example of configuration of delay devices. The input clock 190 input from an input part IN of the delay device A is output from an output part OUT of the delay device A. The input clock 190 input from an input part IN of the delay device B is output from an output part OUT of the delay device B.

The delay devices A and B each include an even number of delay buffers 21 and 22 (two delay buffers 21 and 22 in the case illustrated in FIG. 5) coupled in series with each other. The delay devices A and B each include a delay buffer 21 having the input clock 190 as an input thereto and a delay buffer 22 having an output of the delay buffer 21 as an input thereto. The input clock 190 output from the delay buffer 22 is input to a delay buffer in a first stage within a delay device in a subsequent stage.

The delay buffer 21 includes an inverter 11, an inverter 12 having an output of the inverter 11 as an input thereto, and a resistance part 31 coupled between an output of the inverter 12 and an input of the inverter 11. The inverters 11 and 12 each invert an input/output logic level.

The delay buffer 22 includes an inverter 13, an inverter 14 having an output of the inverter 13 as an input thereto, and a resistance part 32 coupled between an output of the inverter 14 and an input of the inverter 13. The inverters 13 and 14 each invert an input/output logic level.

A common control voltage VC is applied to each of the resistance parts 31 and 32. The resistance parts 31 and 32 are controlled by the control voltage VC. The control voltage VC corresponds to the control voltage VA1 as an example of a first control signal in the case where the configuration of FIG. 5 represents the delay device A, and the control voltage VC corresponds to the control voltage VB as an example of a second control signal in the case where the configuration of FIG. 5 represents the delay device B.

The respective resistance values of the resistance parts 31 and 32 are a value corresponding to the control voltage VC. For example, the magnitude of current flowing through the delay buffers 21 and 22 within the delay device changes according to the value of the control voltage VC. The delay time of the delay device changes according to the change in the magnitude of the current. The resistance parts 31 and 32 are a transistor such as a metal oxide semiconductor field effect transistor (MOSFET) or the like.

The delay devices A and B each include an even number of delay buffers (two delay buffers 21 and 22 in the mode illustrated in FIG. 5) coupled in series with each other. Thus, the logic level of the input clock 190 is the same at the input part IN and the output part OUT. In addition, because a rising speed and a falling speed of edges of the input clock 190 are different from each other, the difference between both speeds may be canceled out by coupling the even number of delay buffers in series with each other.

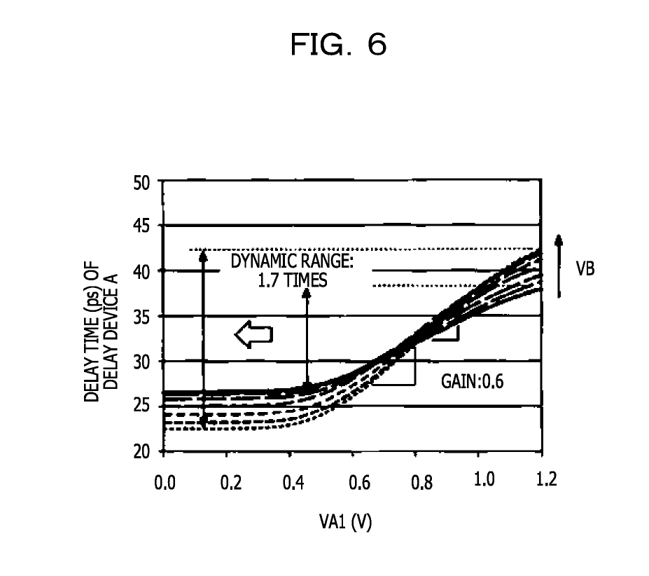

FIG. 6 is a diagram illustrating an example of delay time characteristics in the configuration illustrated in FIG. 5. The dynamic range of the delay time of the delay device A is expanded 1.7 times by increasing the control voltage VB. On the other hand, the gain in a state of a small dynamic range is 0.6 times that in a state of a large dynamic range.

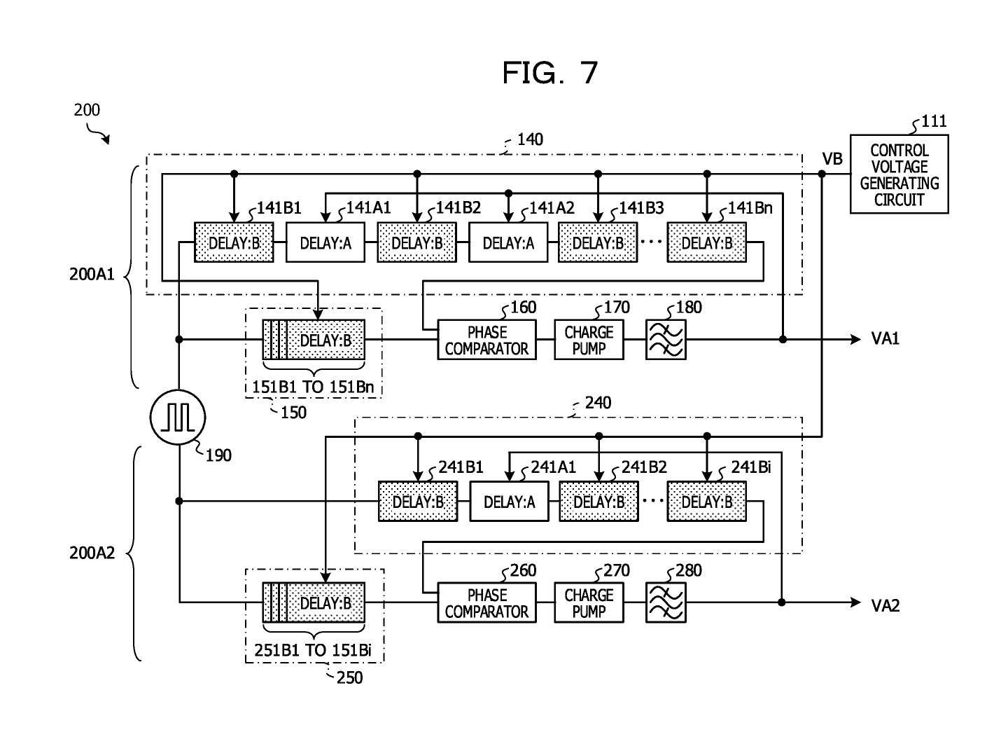

FIG. 7 is a diagram illustrating an example of a configuration of a DLL circuit according to a second embodiment of the present disclosure. A DLL circuit 200 illustrated in FIG. 7 includes a delay locked loop part 200A1, a delay locked loop part 200A2, and a control voltage generating circuit 111. The DLL circuit 200 may, for example, be applied to the DLL circuit 100A in FIG. 2. For example, the delay locked loop part 200A1 may be applied to the DLL unit 100A1, and the delay locked loop part 200A2 may be applied to the DLL unit 100A2.

The delay locked loop parts 200A1 and 200A2 each have the same configuration as the configuration illustrated in FIG. 3, and therefore description thereof will be simplified by citing the foregoing description.

The delay locked loop part 200A1 is an example of a first delay locked loop part. The delay locked loop part 200A2 is an example of a second delay locked loop part. The delay locked loop part 200A1 includes a delay circuit 140, a delay circuit 150, a phase comparator 160, a charge pump 170, and a low-pass filter 180. The delay locked loop part 200A2 includes a delay circuit 240, a delay circuit 250, a phase comparator 260, a charge pump 270, and a low-pass filter 280.

The delay circuit 240 is an example of a first delay circuit. The delay circuit 240 includes j delay devices A (delay devices 241A1 to 241Aj) having a mutually identical configuration and i delay devices B (delay devices 141B1 to 141Bi) having a mutually identical configuration. j and i each represent a natural number.

The delay circuit 250 is an example of a second delay circuit. The delay circuit 250 includes i delay devices B (delay devices 251B1 to 251Bi) having a mutually identical configuration. For example, the delay circuit 250 includes the delay devices B equal in number and identical in configuration to the i delay devices B within the delay circuit 240. The delay devices B within the delay circuit 250 are an example of third delay devices. The delay circuit 250 has a configuration in which the i delay devices B (delay devices 251B1 to 251Bi) are coupled in series with each other.

The number m of delay devices A within the delay locked loop part 200A1 is different from the number j of delay devices A within the delay locked loop part 200A2. For example, j is smaller than m. In addition, the control voltage generating circuit 111 outputs a control voltage VB common to the delay locked loop part 200A1 and the delay locked loop part 200A2.

Hence, as in the foregoing, a control voltage VA1 in a locked state may be used as a voltage that may accurately generate a total delay time (delay time TA) obtained by summing the respective delay times of the m delay devices A. In addition, a control voltage VA2 in a locked state may be used as a voltage that may accurately generate a total delay time (delay time TB) obtained by summing the respective delay times of the j delay devices A. For example, the DLL circuit 200 may output the control voltage VA1 in a locked state as a voltage that may accurately generate the delay time TA, and may output the control voltage VA2 in a locked state as a voltage that may accurately generate the delay time TB. When j is smaller than m, the delay time TB is longer than the delay time TA.

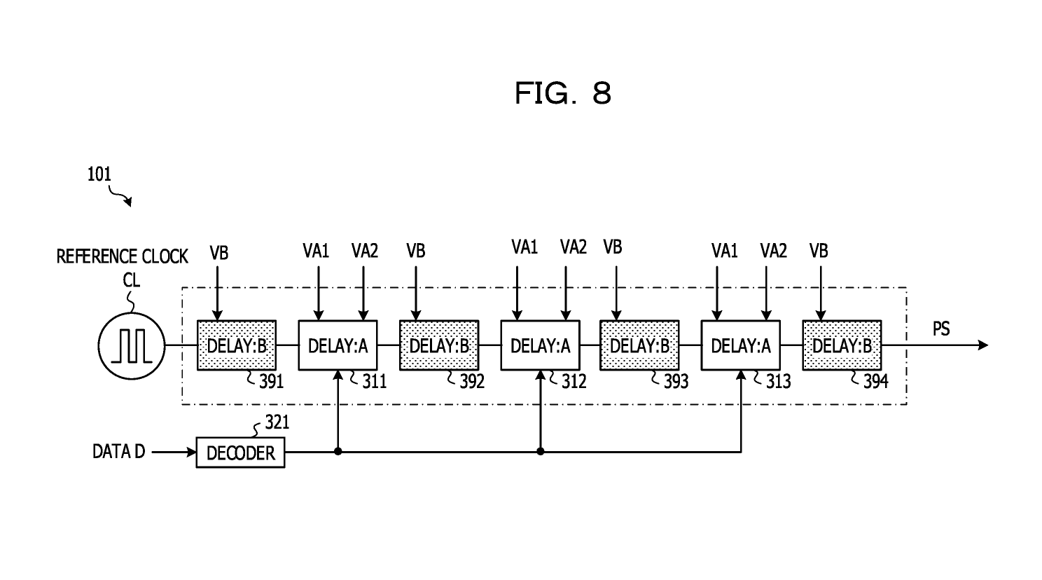

FIG. 8 is a diagram illustrating an example of a configuration of a pulse position modulation circuit (PPM circuit). A PPM circuit 101 illustrated in FIG. 8 may be applied to the PPM circuit 101 in FIG. 2.

The control voltage VB generated by the DLL circuit 200 in FIG. 7 is input to delay devices B within the PPM circuit 101 in FIG. 8. The control voltages VA1 and VA2 generated by the DLL circuit 200 in FIG. 7 are input to delay devices A within the PPM circuit 101 in FIG. 8. The delay time of the modulated signal PS is changed by switching the control voltage VA1 and the control voltage VA2 so as to correspond to the input data D within the PPM circuit 101. A pulse position modulation is thereby realized. Details of the pulse position modulation will next be described.

The PPM circuit 101 illustrated in FIG. 8 includes a delay path 310 and a decoder 321.

The delay path 310 includes a plurality of delay devices A and B (seven delay devices A and B in the case illustrated in FIG. 8) coupled in series with each other. For example, the delay path 310 includes three delay devices A (delay devices 311 to 313) having a mutually identical configuration and four delay devices B (delay devices 391 to 394) having a mutually identical configuration. The reference clock CL is input to the delay device 391. The modulated signal PS is output from the delay device 394. The output of a delay device B becomes the input of a delay device A, and the output of the delay device A becomes the input of a delay device B.

The reference clock CL passes through the seven delay devices A and B, and thereby the modulated signal PS is output. The decoder 321 is an example of a changing circuit that changes a delay time by which the reference clock CL is delayed in each of the three delay devices A (delay devices 311, 312, and 313) according to the input data D.

The decoder 321 changes a control voltage that controls the delay time by which the reference clock CL is delayed in each of the delay devices 311, 312, and 313 according to the input data D. It is thereby possible to adjust the respective delay times of the delay devices 311, 312, and 313 individually, and suppress variations in the delay time of the whole of the delay path 310.

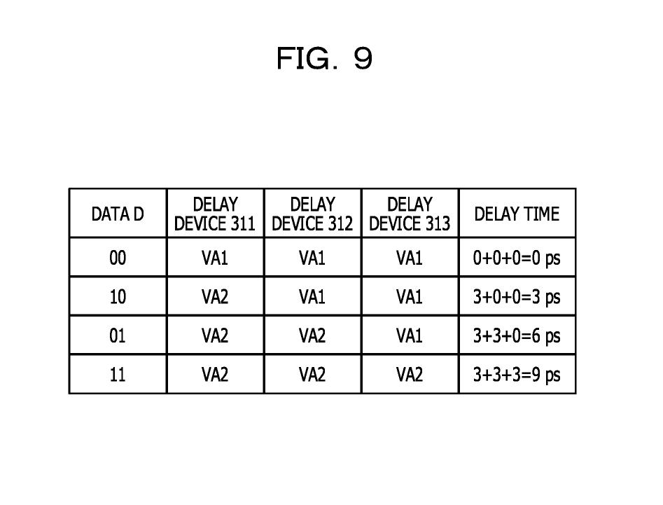

FIG. 9 is a diagram illustrating an example of variations in delay time generated by a delay path. The decoder 321 selects control voltages that control the delay time by which the reference clock CL is delayed from the control voltages VA1 and VA2 according to the input data D.

In a case where the input data D of 2 bits is “00,” the decoder 321 sets the control voltages that control the respective delay times of the delay devices 311, 312, and 313 to the control voltage VA1, the control voltage VA1, and the control voltage VA1, respectively. In a case where the input data D of 2 bits is “01,” the decoder 321 sets the control voltages that control the respective delay times of the delay devices 311, 312, and 313 to the control voltage VA2, the control voltage VA1, and the control voltage VA1, respectively. In a case where the input data D of 2 bits is “10,” the decoder 321 sets the control voltages that control the respective delay times of the delay devices 311, 312, and 313 to the control voltage VA2, the control voltage VA2, and the control voltage VA1, respectively. In a case where the input data D of 2 bits is “11,” the decoder 321 sets the control voltages that control the respective delay times of the delay devices 311, 312, and 313 to the control voltage VA2, the control voltage VA2, and the control voltage VA2, respectively.

When the control voltages are thus set, the temporal position of the pulsed modulated signal PS changes in increments of 3 ps in accordance with the input data D.

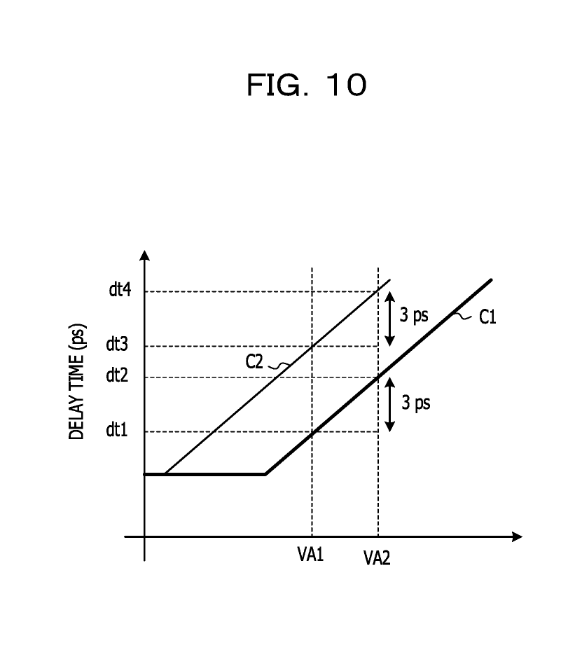

FIG. 10 is a diagram illustrating an example of delay device characteristics. The delay devices 311, 312, and 313 each have a mutually identical delay characteristic. C1 represents a typical delay characteristic of the delay devices. C2 represents a delay characteristic when variations of individual differences in the delay devices occur.

In a state in which the delay characteristic is C1, when the control voltage VA1 is selected as a voltage that controls the delay time, the delay time of each delay device is dt1. In the state in which the delay characteristic is C1, when the control voltage VA2 is selected as a voltage that controls the delay time, the delay time of each delay device is dt2. On the other hand, in a state in which the delay characteristic is C2, when the control voltage VA1 is selected as a voltage that controls the delay time, the delay time of each delay device is dt3. In the state in which the delay characteristic is C2, when the control voltage VA2 is selected as a voltage that controls the delay time, the delay time of each delay device is dt4.

However, the value of the control voltage VA1 and the value of the control voltage VA2 are set in advance such that a difference between the delay time when the control voltage VA1 is selected and the delay time when the control voltage VA2 is selected is a delay time desired to be generated in position modulation. Because a rate of change of the delay time with respect to the control voltage is substantially the same between C1 and C2, substantially the same delay time is obtained even when the delay characteristic of the delay device changes from C1 to C2 due to a characteristic variation as long as a difference between two control voltages (VA2−VA1) is the same. Hence, variations in delay time may be suppressed.

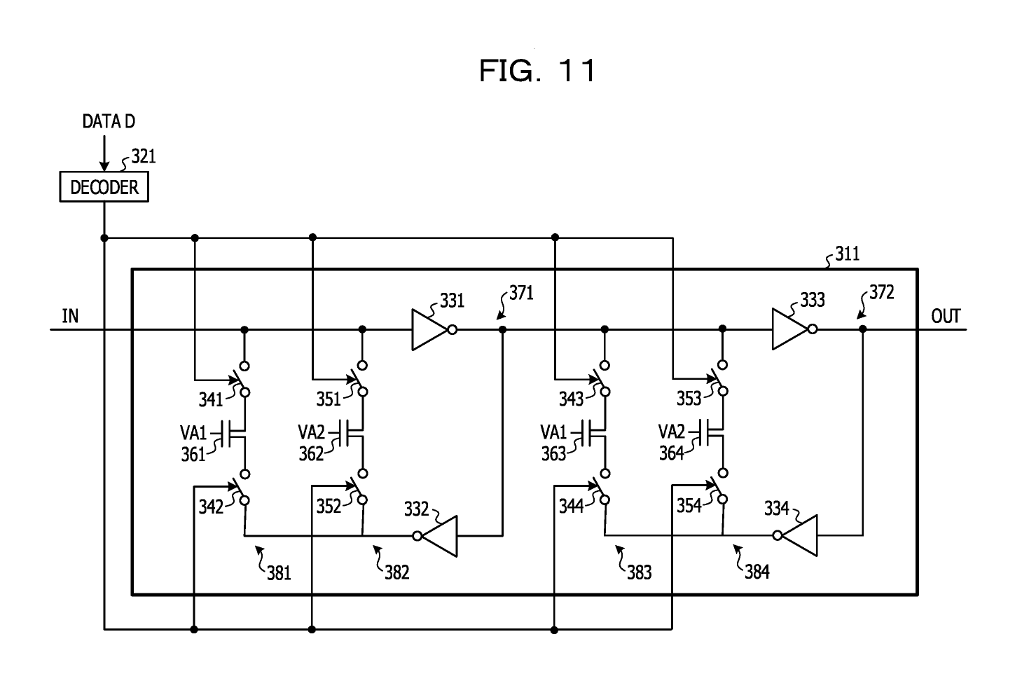

FIG. 11 is a diagram illustrating one concrete example of configuration of a delay device. FIG. 11 illustrates a configuration of the delay device 311. However, the other delay devices 312 and 313 each also have the same configuration as the delay device 311. The reference clock CL input from an input part IN of the delay device 311 is output from an output part OUT of the delay device 311.

The delay device 311 includes an even number of unit circuits 371 and 372 (two unit circuits 371 and 372 in the case illustrated in FIG. 11) coupled in series with each other. The delay device 311 includes the unit circuit 371 having the reference clock CL as an input thereto and the unit circuit 372 having an output of the unit circuit 371 as an input thereto. The reference clock CL output from the unit circuit 372 is input to a unit circuit in a first stage within the delay device 312 in a subsequent stage.

The unit circuit 371 includes an inverter 331, an inverter 332 having the output of the inverter 331 as an input thereto, and control paths 381 and 382 equal in number to the control voltages VA1 and VA2 (for example, two control paths). The control paths 381 and 382 are both coupled between an output of the inverter 332 and an input of the inverter 331. The inverters 331 and 332 each invert an input/output logic level.

The unit circuit 372 includes an inverter 333, an inverter 334 having the output of the inverter 333 as an input thereto, and control paths 383 and 384 equal in number to the control voltages VA1 and VA2 (for example, two control paths). The control paths 383 and 384 are both coupled between an output of the inverter 334 and an input of the inverter 333. The inverters 333 and 334 each invert an input/output logic level.

The decoder 321 selects a path that controls a time by which the reference clock CL is delayed according to the control voltages VA1 and VA2 from the control paths 381 to 384 according to the input data D.

The control path 381 to which the control voltage VA1 is applied includes interrupting parts 341 and 342 and a resistance part 361. The control path 383 to which the control voltage VA1 is applied includes interrupting parts 343 and 344 and a resistance part 363. The control path 382 to which the control voltage VA2 is applied includes interrupting parts 351 and 352 and a resistance part 362. The control path 384 to which the control voltage VA2 is applied includes interrupting parts 353 and 354 and a resistance part 364.

The interrupting parts 341 and 342 interrupt the coupling of the control path 381 between the output of the inverter 332 and the input of the inverter 331 based on a signal output from the decoder 321 according to the input data D. The interrupting parts 351 and 352 interrupt the coupling of the control path 382 between the output of the inverter 332 and the input of the inverter 331 based on a signal output from the decoder 321 according to the input data D. The interrupting parts 343 and 344 interrupt the coupling of the control path 383 between the output of the inverter 334 and the input of the inverter 333 based on a signal output from the decoder 321 according to the input data D. The interrupting parts 353 and 354 interrupt the coupling of the control path 384 between the output of the inverter 334 and the input of the inverter 333 based on a signal output from the decoder 321 according to the input data D. A transfer gate using a transistor is cited as a concrete example of each interrupting part.

The control voltage VA1 is applied to the resistance part 361. When the interrupting parts 341 and 342 in front of and in the rear of the resistance part 361 are both in an on state, the resistance value of the resistance part 361 is a value corresponding to the control voltage VA1 (state in which the control voltage VA1 is selected). Similarly, the control voltage VA1 is applied to the resistance part 363. When the interrupting parts 343 and 344 in front of and in the rear of the resistance part 363 are both in an on state, the resistance value of the resistance part 363 is a value corresponding to the control voltage VA1 (state in which the control voltage VA1 is selected).

On the other hand, the control voltage VA2 is applied to the resistance part 362. When the interrupting parts 351 and 352 in front of and in the rear of the resistance part 362 are both in an on state, the resistance value of the resistance part 362 is a value corresponding to the control voltage VA2 (state in which the control voltage VA2 is selected). Similarly, the control voltage VA2 is applied to the resistance part 364. When the interrupting parts 353 and 354 in front of and in the rear of the resistance part 364 are both in an on state, the resistance value of the resistance part 364 is a value corresponding to the control voltage VA2 (state in which the control voltage VA2 is selected).

For example, the magnitude of currents flowing through the control paths 381 and 383 in the state in which the control voltage VA1 is selected is different from the magnitude of currents flowing through the control paths 382 and 384 in the state in which the control voltage VA2 is selected. Due to this difference, the delay time of the delay device 311 changes between a delay time in the state in which the control voltage VA1 is selected and a delay time in the state in which the control voltage VA2 is selected.

The resistance parts 361 to 364 are, for example, a transistor such as a MOSFET or the like. Variations in threshold value of these transistors relatively greatly affect variations in the delay time of each delay device.

The delay device 311 includes an even number of unit circuits (two unit circuits 371 and 372 in the mode illustrated in FIG. 11) coupled in series with each other. Thus, the logic level of the reference clock CL is the same at the input part IN and the output part OUT. In addition, because a rising speed and a falling speed of edges of the reference clock CL are different from each other, the difference between both speeds may be canceled out by coupling the even number of unit circuits in series with each other.

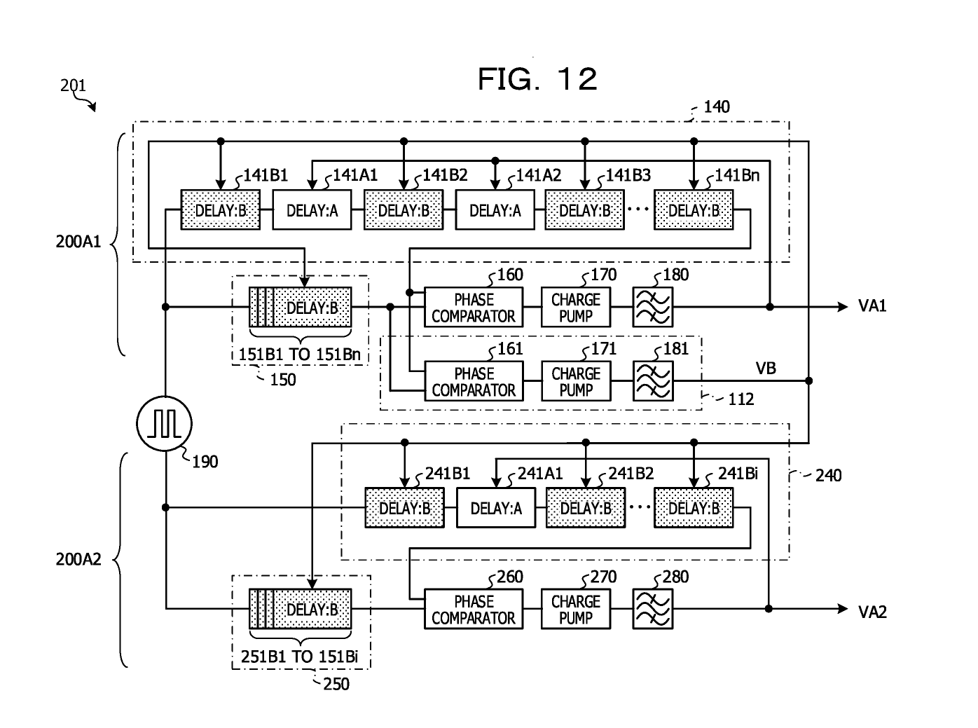

FIG. 12 is a diagram illustrating another example of a configuration of a DLL circuit according to the second embodiment of the present disclosure. FIG. 12 illustrates a first example of a unit that generates the control voltage VB. The DLL circuit 201 illustrated in FIG. 12 includes a delay locked loop part 200A1, a delay locked loop part 200A2, and a control voltage generating circuit 112. FIG. 12 is different from FIG. 7 in terms of the control voltage generating circuit as an example of a second control circuit. The control voltage generating circuit 112 in FIG. 12 outputs a control voltage VB common to the delay locked loop part 200A1 and the delay locked loop part 200A2.

The control voltage generating circuit 112 performs output feedback of the control voltage VB by a control loop having a narrower band than a control loop in which the charge pump 170 and the low-pass filter 180 perform output feedback of the control voltage VA1. The control voltage generating circuit 112 performs output feedback of the control voltage VB by a control loop having a narrower band than a control loop in which the charge pump 270 and the low-pass filter 280 perform output feedback of the control voltage VA2.

The control voltage generating circuit 112 includes a phase comparator 161, a charge pump 171, and a low-pass filter 181. The phase comparator 161, the charge pump 171, and the low-pass filter 181 respectively have the same configurations as the phase comparator 160, the charge pump 170, and the low-pass filter 180.

Operation of the DLL circuit 201 of FIG. 12 will be described. First, the control voltages VA1 and VA2 are controlled by the wide-band control loops. In a state in which the DLL circuit 201 is not locked even when the control voltages VA1 and VA2 are changed to a limit of a voltage variable range, the control voltage VB is controlled by the narrow-band control loop, and the control voltage VB is slightly changed in a direction of locking the DLL circuit 201. In a state in which the control voltage VB is thus slightly changed, output feedback is performed by the control loops of the control voltages VA1 and VA2 once again. Repeating such control operation may change the control voltage VB until the DLL circuit 201 is locked.

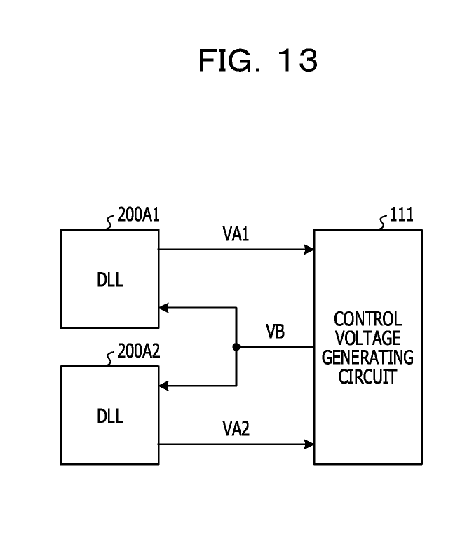

FIG. 13 is a diagram illustrating an example of configuration of the DLL circuit according to the second embodiment of the present disclosure. FIG. 13 illustrates a second example of the unit that generates the control voltage VB. The DLL circuit illustrated in FIG. 13 includes a delay locked loop part 200A1, a delay locked loop part 200A2, and a control voltage generating circuit 111 (see FIG. 7, for example, for details of the circuit).

The control voltage generating circuit 111 in FIG. 13 controls the control voltage VB according to the control voltage VA1 generated by the delay locked loop part 200A1 and the control voltage VA2 generated by the delay locked loop part 200A2. For example, the control voltage generating circuit 111 generates the control voltage VB according to a result of monitoring the control voltages VA1 and VA2.

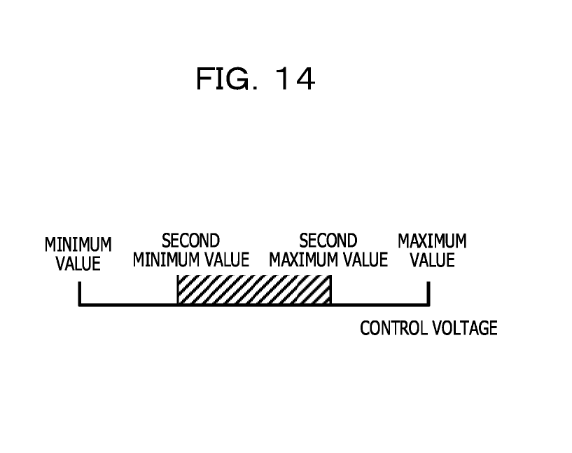

FIG. 14 is a diagram of assistance in explaining an example of a method of generating the control voltage VB by the mode of FIG. 13. FIG. 14 illustrates a voltage range that may be taken by the control voltages VA1 and VA2. A case in which the control voltage VA1 is in a voltage range of a minimum value to a second minimum value or a case in which the control voltage VA2 is in a voltage range of a second maximum value to a maximum value indicates that the DLL circuit is not in a locked state. A case in which the control voltages VA1 and VA2 are in a voltage range (hatched region illustrated in FIG. 14) of the second minimum value to the second maximum value indicates that the DLL circuit is in a locked state.

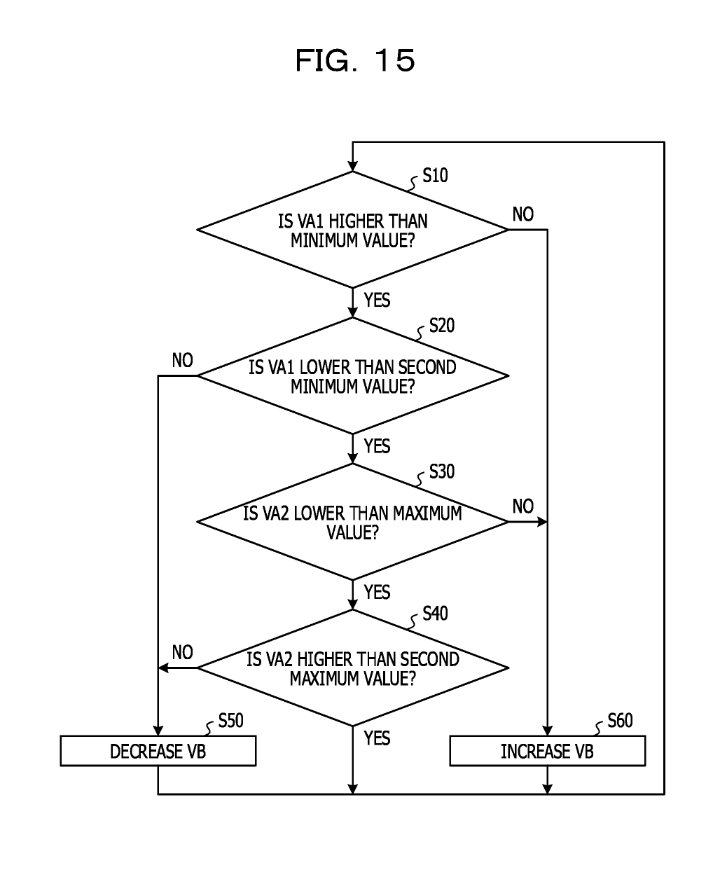

FIG. 15 is a flowchart illustrating an example of the method of generating the control voltage VB by the mode of FIG. 13. FIG. 15 will be described in the following with reference to FIGS. 13 and 14.

The control voltage generating circuit 111 determines whether or not the control voltage VA1 is higher than the minimum value (step S10). When the control voltage VA1 is equal to or lower than the minimum value (No in step S10), the DLL circuit is not in a locked state, and therefore the control voltage generating circuit 111 increases the control voltage VB (step S60), and makes the determination of step S10 again.

When the control voltage VA1 is higher than the minimum value (Yes in step S10), the control voltage generating circuit 111 determines whether or not the control voltage VA1 is lower than the second minimum value (step S20). When the control voltage VA1 is equal to or higher than the second minimum value (No in step S20), the control voltage generating circuit 111 decreases the control voltage VB (step S50), and makes the determination of step S10 again.

When the control voltage VA1 is lower than the second minimum value (Yes in step S20), the control voltage generating circuit 111 determines whether or not the control voltage VA2 is lower than the maximum value (step S30). When the control voltage VA2 is equal to or higher than the maximum value (No in step S30), the DLL circuit is not in a locked state, and therefore the control voltage generating circuit 111 increases the control voltage VB (step S60), and makes the determination of step S10 again.

When the control voltage VA2 is lower than the maximum value (Yes in step S30), the control voltage generating circuit 111 determines whether or not the control voltage VA2 is higher than the second maximum value (step S40). When the control voltage VA2 is equal to or lower than the second maximum value (No in step S40), the control voltage generating circuit 111 decreases the control voltage VB (step S50), and makes the determination of step S10 again. When the control voltage VA2 is higher than the second maximum value (Yes in step S40), the DLL circuit is in a locked state, and therefore the control voltage generating circuit 111 makes the determination of step S10 again.

Delay locked loop circuits have been described above based on embodiments. However, the present disclosure is not limited to the foregoing embodiments. Various modifications and improvements such as combination and replacement with a part or the whole of other embodiments and the like are possible within the scope of the present disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A delay locked loop circuit comprising:
a first delay circuit that includes a plurality of first delay devices and a plurality of second delay devices, the plurality of first delay devices and the plurality of second delay devices are coupled in series with each other;
a second delay circuit that includes a plurality of third delay devices equal in number and identical in configuration to the plurality of second delay devices, the plurality of third delay devices are coupled in series with each other;
a phase comparator that outputs a phase difference between a first delayed clock output from the first delay circuit and a second delayed clock output from the second delay circuit;
a first control circuit that outputs a first control signal that controls a time by which the clock is delayed in each first delay device according to the phase difference; and
a second control circuit that outputs a second control signal that controls a time by which the clock is delayed in each second delay device and each third delay device.

2. The delay locked loop circuit according to claim 1, wherein
the first delay circuit has a configuration in which an output of the second delay device is input to the first delay device.

3. The delay locked loop circuit according to claim 2, wherein
the first delay circuit has a configuration in which the first delay device is sandwiched between second delay devices.

4. The delay locked loop circuit according to claim 1, wherein
the second control circuit performs output feedback of the second control signal by a control loop having a narrower band than a control loop in which the first control circuit performs output feedback of the first control signal.

5. The delay locked loop circuit according to claim 1, wherein
the second control circuit controls the second control signal according to the first control signal.

6. The delay locked loop circuit according to claim 1, wherein
the first delay device, the second delay device, and the third delay devices each include a first inverter, a second inverter having an output of the first inverter as an input to the second inverter, and a resistance part coupled between an output of the second inverter and an input of the first inverter,
the resistance part of the first delay device is controlled by the first control signal, and
the resistance parts of the second delay device and the third delay devices are controlled by the second control signal.

7. The delay locked loop circuit according to claim 6, wherein
the first delay device, the second delay device, and the third delay devices each include an even number of delay buffers coupled in series with each other, and
each of the even number of delay buffers includes the first inverter, the second inverter, and the resistance part.

8. The delay locked loop circuit according to claim 1, wherein
the delay locked loop circuit includes a first delay locked loop part and a second delay locked loop part each including the first delay circuit, the second delay circuit, the phase comparator, and the first control circuit,
the number of first delay devices in the first delay locked loop part is different from the number of first delay devices in the second delay locked loop part, and
the second control circuit outputs the second control signal common to the first delay locked loop part and the second delay locked loop part.

9. A transmitter comprising:
a delay locked loop circuit,
the delay locked loop circuit including
a first delay circuit that includes a plurality of first delay devices and a plurality of second delay devices, the plurality of first delay devices and the plurality of second delay devices are coupled in series with each other,
a second delay circuit that includes a plurality of third delay devices equal in number and identical in configuration to the plurality of second delay devices, the plurality of third delay devices are coupled in series with each other;
a phase comparator that outputs a phase difference between a first delayed clock output from the first delay circuit and a second delayed clock output from the second delay circuit,
a first control circuit that outputs a first control signal that controls a time by which the clock is delayed in each first delay device according to the phase difference,
a second control circuit that outputs a second control signal that controls a time by which the clock is delayed in each second delay device and each third delay device, and
a first delay locked loop part and a second delay locked loop part each including the first delay circuit, the second delay circuit, the phase comparator, and the first control circuit; and
a pulse position modulation circuit that outputs a modulated signal based on the first control signal output from the first control circuit of the first delay locked loop part and the first control signal output from the first control circuit of the second delay locked loop part; wherein
the number of first delay devices in the first delay locked loop part being different from the number of first delay devices in the second delay locked loop part,
the second control circuit outputting the second control signal common to the first delay locked loop part and the second delay locked loop part, and
the transmitter radio-transmitting a signal based on the modulated signal.
